(19) United States
(12) Patent Application Publication
(10) Pub. No.: US 2007/0296055 A1
(43) Pub. Date: Dec. 27, 2007

(54) RF INTEGRATED CIRCUIT WITH ESD PROTECTION AND ESD PROTECTION APPARATUS THEREOF

(76) Inventors: Albert Kuo Huei Yen, San Jose, CA (US); Chang-Ching Wu, Hsinchu City (TW); Tzu-Chao Lin, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,101

(22) Filed: Jun. 23, 2006

(51) Int. Cl. H01L 29/00

(52) U.S. Cl. 257/531

(57) ABSTRACT

A radio frequency (RF) integrated circuit with electrostatic discharge (ESD) protection and an ESD protection apparatus thereof are provided. The ESD protection apparatus includes a substrate, an RF bonding pad, and an ESD protection unit. The RF bonding pad for transmitting RF signal is disposed upon the substrate. The ESD protection unit is disposed under the RF bonding pad. Wherein, The ESD protection unit includes an inductor electrically connected between the RF bonding pad and the power rail.

### BACKGROUND OF THE INVENTION

1. Field of Invention

The present invention relates to an electrostatic discharge (ESD) protection apparatus. More particularly, the present invention relates to a radio frequency (RF) integrated circuit with ESD protection and an ESD protection apparatus thereof.

2. Description of Related Art

Electrostatic discharge can be substantially divided into human-body model (HBM), machine model (MM), and charge-device model (CDM). The electrostatic discharge impact can not be avoided in the electronic circuit in actual usage environment, and part of the devices may be damaged if there is no suitable protection means. When an electrostatic discharge occurs, a great deal of electrostatic discharge current may produce high temperature that may damage the semiconductor devices. Therefore, how to protect the internal circuit of the integrated circuit from the impact of the electrostatic discharge current is crucial. In order to avoid the abovementioned situation, the integrated circuit must have electrostatic discharge protection function.

FIG. 1 is a diagram of a conventional electrostatic discharge protection apparatus in an integrated circuit. The conventional electrostatic discharge protection apparatus includes diodes D11, D12 and a resistor R11. The diode D11 is electrically connected between a power rail VDD and a bonding pad 110 in reverse-biased configuration, and the diode D12 is also electrically connected between a power rail VSS and the bonding pad 110 in reverse-biased configuration. In general, the power rails VSS and VDD are suitable to respectively provide a ground voltage and a system voltage for the internal circuit 120.

When the bonding pad 110 produces a positive pulse current due to the electrostatic discharge, the resistor R11 can prevent most of the positive pulse current from flowing into the internal circuit 120, and at the same time, the diode D11 can guide most of the positive pulse current to the power rail VDD. Similarly, when the bonding pad 110 produces a negative pulse current due to the electrostatic discharge, the resistor R11 can prevent most of the negative pulse current from flowing into the internal circuit 120, and at the same time, the diode D12 can guide most of the negative pulse current to the power rail VSS.

For the radio frequency (RF) integrated circuit, a parasitic capacitor C11 may be inevitably formed between the bonding pad 110 and the substrate. The parasitic capacitor C11 may filter out the RF signal of the bonding pad 110, resulting in transmission error of RF signal; therefore, the capacitance of the parasitic capacitor C11 must be reduced as much as possible. Accordingly, the RF bonding pad is disposed upon the uppermost metal layer of the integrated circuit in the conventional technologies, and a vacuum is kept between the RF bonding pad and the substrate to reduce the capacitance of the parasitic capacitor C11. In other words, no devices are disposed under the conventional RF bonding pad.

In addition, the abovementioned conventional electrostatic discharge protection apparatus is not suitably applicable. As the RF signal received by the RF integrated circuit is usually very weak, the R11 protecting the internal circuit 120 may consume the energy of the RF signal that causes RF signal transmitting error. Therefore, recently, some publications have proposed a variety of electrostatic discharge protection apparatuses suitable for RF circuit. For example, an inductor used as the electrostatic discharge protection unit is disclosed in Vol. 40, No. 7, pages 1434-1442, July 2005, Journal of Solid-State Circuit, Institute of Electrical and Electronic Engineers (IEEE). FIG. 2 is a diagram of the conventional electrostatic discharge protection apparatus with an inductor. As the frequency of the RF signal through the RF bonding pad 210 is usually up to 1 GHz or higher, the inductor L21 can provide very high resistance for the RF signal in normal operation. That is, in normal operation, the inductor L21 is just as an open circuit, so that the weak RF signal can be directly transmitted between the RF bonding pad 210 and the internal circuit 220. As the impulse period of the electrostatic discharge is far longer than the RF signal, when an electrostatic discharge occurs in the RF bonding pad 210 and the power rail VSS is connected to the ground, the impulse current resulting from the electrostatic discharge may be guided to the power rail VSS by the inductor L21. When an electrostatic discharge occurs in the RF bonding pad 210 and the power rail VDD is connected to the ground, the impulse current resulting from the electrostatic discharge may be guided to the power rail VDD through the inductor L21, the power rail VSS, the diode D21.

Other electrostatic discharge protection apparatuses suitable in RF circuit are also disclosed, for example, in US Patent Application No. US 20030183403 and U.S. Pat. No. 6,885,534. The inductor is electrically connected in the RF signal path between the internal circuit and the RF bonding pad in the conventional technologies, or the inductor is connected with the diode in series or parallel connections so as to act as the electrostatic discharge protection apparatus.

However, as the inductor suitable for the electrostatic discharge protection must occupy a great deal of chip area, the cost increases substantially.

### SUMMARY OF THE INVENTION

Accordingly, the present invention is directed to provide an electrostatic discharge protection apparatus, suitable for protecting the internal circuit which receives/emits RF signal from damage resulting from the electrostatic discharge, and at the same time, the normal RF signal transmission is not impacted. In addition, the electrostatic discharge protection unit is disposed under the RF bonding pad, so that the chip area can be substantially saved and the fabrication cost is reduced.

Another aspect of the present invention is to provide an RF integrated circuit with an electrostatic discharge (ESD) protection, which can guide the electrostatic impulse current to the power rail in time so as to avoid the damage of the internal circuit when an electrostatic discharge occurs in the RF bonding pad. In addition, the electrostatic discharge protection unit is disposed under the RF bonding pad, so that the chip area can be substantially saved and the fabrication cost is reduced.

According to the above aspects, the present invention provides an ESD protection apparatus which includes a substrate, a RF bonding pad, and an ESD protection unit. The RF bonding pad, suitable for transmitting RF signal, is disposed upon the substrate. The ESD protection unit is disposed under the RF bonding pad. Wherein, The ESD protection unit includes an inductor electrically connected between the RF bonding pad and the power rail.

According to another standpoint, the present invention provide an RF integrated circuit with ESD protection; the RF integrated circuit includes a substrate, a power rail, an RF bonding pad, an internal circuit, and an ESD protection unit. Both of the power rail and the RF bonding pad are disposed upon the substrate. The RF bonding pad is suitable for transmitting the RF signal. The internal circuit is disposed in the substrate and electrically connected with the RF bonding pad, so as to transit the RF bonding pad to receive/emit RF signal from/to outside. The ESD protection unit is disposed under the RF bonding pad. Wherein, the ESD protection unit includes an inductor electrically connected between the RF bonding pad and the power rail.

According to the present invention, the ESD protection unit is disposed under the RF bonding pad, so that the chip area can be substantially saved and the fabrication cost is reduced. In addition, as the ESD protection unit includes an inductor electrically connected between the RF bonding pad and the power rail, the internal circuit for receiving/emitting RF signal can be protected from damage resulting from ESD, and at the same time, the normal RF signal transmission is not impacted.

In order to the make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a diagram of a conventional electrostatic discharge (ESD) protection apparatus within the integrated circuit.

FIG. 2 is a diagram of a conventional EDS protection apparatus with an inductor.

FIG. 3 is a block diagram of an RF integrated circuit with ESD protection according to the embodiment of the present invention.

FIG. 4 is a cross-sectional diagram of the RF bonding pad 310 and the ESD protection unit thereof in the RF integrated circuit 300 in FIG. 3 according to the embodiment of the present invention.

FIG. 5 is a platform view of the inductor in spiral arrangement in the ESD protection unit 330 according to the embodiment of the present invention.

FIG. 6 is a perspective view of the inductor in stack arrangement in the ESD protection unit 330 according to the embodiment of the present invention.

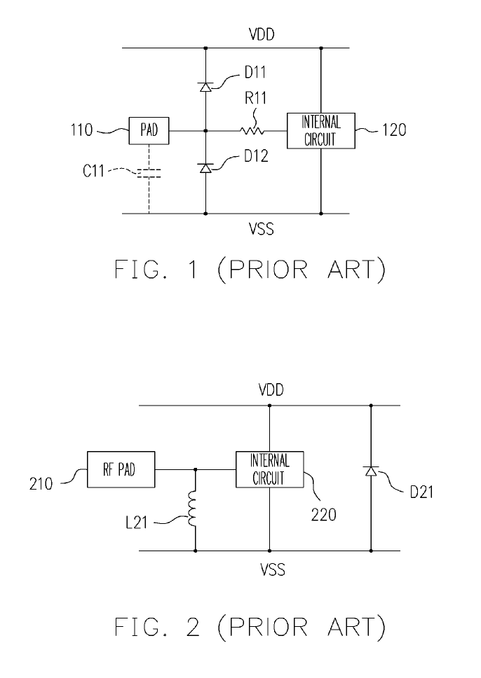

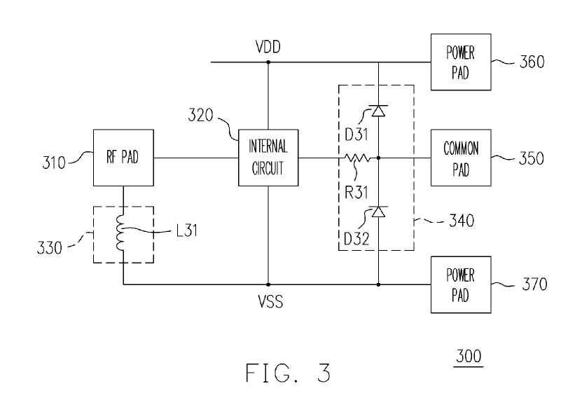

### DESCRIPTION OF EMBODIMENTS

FIG. 3 is a block diagram of an RF integrated circuit with ESD protection according to the embodiment of the present invention. Please referring to FIG. 3, in the RF integrated circuit 300, an internal circuit 320 receives/emits an RF signal and a common signal respectively through an RF bonding pad 310 and a common bonding pad 350. The power for the internal circuit 320 is provided from outside through a power rail VDD, a power bonding pad 360, a power rail VSS, and a power bonding pad 370. In the embodiment, the power rail VDD is a system voltage rail, and the power rail VSS is a ground rail. In the normal operation, the power rails VSS and VDD are suitable to respectively provide a ground voltage and a system voltage to the internal circuit 120. It needs to be noted that FIG. 3 is a simplified embodiment, and the quantity of actual various pads is not limited by the number shown in FIG. 3.

Usually, a group of ESD protection circuits (for example, ESD protection circuits 340) is disposed between each common bonding pad (for example, a common bonding pad 350) and the internal circuit 320. The ESD protection circuit 340 includes diodes D31, D32, and a resistance R31. The diode D31 is electrically connected between the power rail VDD and the common bonding pad 350 in reverse-biased configuration, and the diode D32 is also electrically connected between the power rail VSS and the common bonding pad 350 in reverse-biased configuration. The resistance R11 is electrically connected between the internal circuit 320 and the common bonding pad 350.

When the common bonding pad 350 produces a positive pulse current resulting from the electrostatic discharge, the resistor R31 can prevent most of the positive pulse current from flowing into the internal circuit 320, and at the same time, the diode D31 can guide most of the positive pulse current to the power rail VDD. Similarly, when the common bonding pad 350 produces a negative pulse current resulting from the electrostatic discharge, the resistor R31 can prevent most of the negative pulse current from flowing into the internal circuit 320, and at the same time, the diode D32 can guide most of the negative pulse current to the power rail VSS.

According to the embodiment, the RF bonding pad 310 is directly connected with the internal circuit 320. The ESD protection unit 330, disposed under the RF bonding pad 310, is directly connected with the RF bonding pad 310. Those skilled in the art can implement the ESD protection unit 330 by any means. According to the embodiment, the ESD protection unit 330 includes an inductor L31. The inductor L31 is electrically connected between the RF bonding pad 310 and the power rail VSS.

As the impulse period of the electrostatic discharge is far longer than the RF signal, for the RF signal in the normal operation, the inductor L31 provides very high resistance. That is, in normal operation, the inductor L31 is served as an open circuit, so that the weak RF signal can be transmitted directly between the RF bonding pad 310 and the internal circuit 320. When an electrostatic discharge occurs in the RF bonding pad 310, the impulse current resulting from the electrostatic discharge may be guided to the power rail VSS by the inductor L31. At this time, if the power bonding pad 370 is connected to the ground, the electrostatic current may flow out of the RF circuit 300 through the power bonding pad 370. When an electrostatic discharge occurs in the RF bonding pad 310, if the common bonding pad 350 is connected to the ground, the electrostatic current may flow out of the RF integrated circuit 300 from the common bonding pad 350 through the inductor L31, the power rail VSS, and the diode D32. Moreover, when an electrostatic discharge occurs in the RF bonding pad 310, if the power bonding pad 360 is connected to the ground, the electrostatic current may flow out of the RF integrated circuit 300 from the power bonding pad 360 through the inductor L31, the power rail VSS, the diode D32, the diode D31, and the power rail VDD.

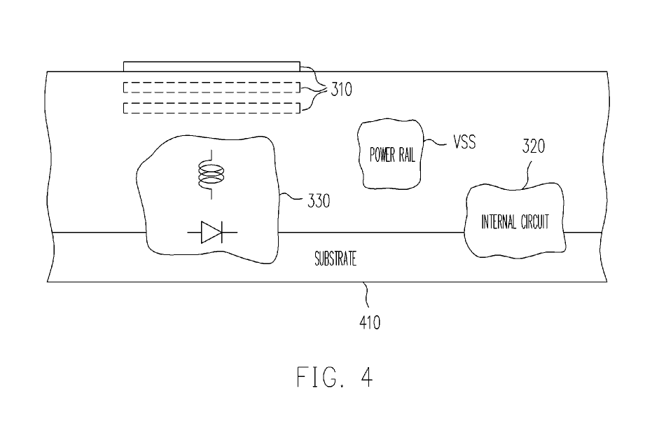

FIG. 4 is a cross-sectional diagram of the RF bonding pad 310 and the ESD protection unit thereof in the RF integrated circuit 300 in FIG. 3 according to the embodiment of the present invention. The ESD protection unit in FIG. 4 includes a substrate 410, the RF bonding pad 310 and the ESD protection unit 330. In order to precisely describe the relationship among the components, the arrangement of the internal connections is not shown in FIG. 4. Referring to FIG. 3 and FIG. 4, the like reference numerals indicate identical or functionally similar elements. The power rail VSS is disposed upon the substrate 410. The RF bonding pad 310 is also disposed upon the substrate 410, suitable for transmitting the RF signal to the internal circuit 320. The RF bonding pad 310 is disposed upon the uppermost metal layer of the integrated circuit. Of course, the RF bonding pad 310 can also be disposed upon the second or third uppermost metal layer. The internal circuit 320 is disposed in the substrate 410. The internal circuit 320 is electrically connected with the RF bonding pad 310 so as to transit the RF bonding pad 310 to receive/emit RF signal from/to outside. The ESD protection unit 330 is disposed under the RF bonding pad 310. Wherein, the ESD protection unit 330 can be implemented as shown in FIG. 3, and other devices (for example, diodes) may also be included to implement the ESD protection unit 330. All of the various changes of the implementation belong to the scope of the present invention. The ESD protection unit 330 is electrically connected between the RF bonding pad 310 and the power rail VSS.

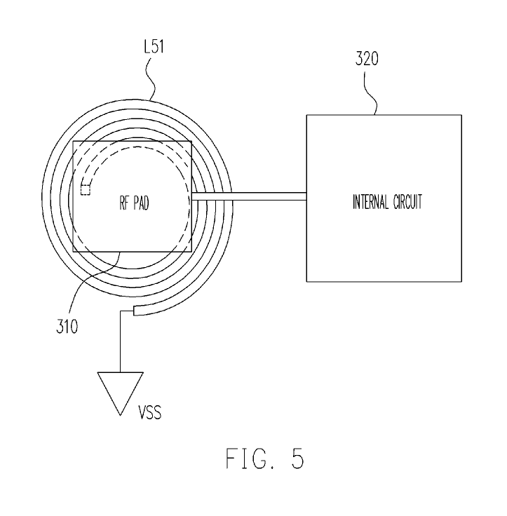

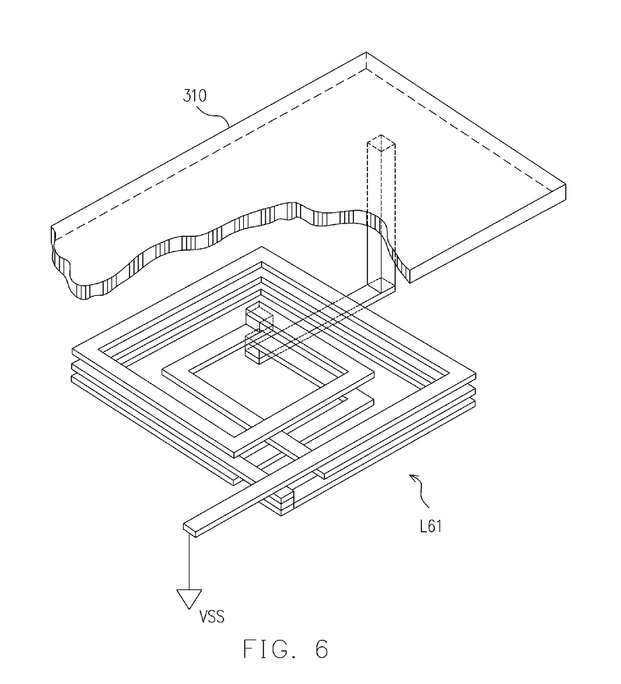

In the abovementioned embodiment, the inductor L31 can be implemented between the RF bonding pad 310 and the substrate 410 by any means. For example, the inductor L31 can be disposed between the RF bonding pad 310 and the substrate 410 in stack or in spiral arrangement. FIG. 5 is a platform view of the inductor in spiral arrangement in the ESD protection unit 330 according to the embodiment of the present invention. Referring to FIG. 5, in the embodiment, the ESD protection unit 330 includes an inductor L51. The inductor L51 is disposed between the RF bonding pad 310 and the substrate in spiral arrangement. In general, the size of the RF bonding pad 310 is about 75 um*84 um, while the size of the spiral inductor L51 for ESD protection is about 100 um*100 um. As the spiral inductor L51 is disposed under the RF bonding pad 310, the chip area can be saved substantially, and the fabrication cost is reduced.

FIG. 6 is a perspective view of the inductor in stack arrangement in the ESD protection unit 330 according to the embodiment of the present invention. Referring to FIG. 6, in the embodiment, the ESD protection unit 330 includes an inductor L61. The inductor L61 is disposed between the RF bonding pad 310 and the substrate in stack arrangement. In general, the size of the stack inductor L51 for ESD protection is about 50 um*50 um, which is less than the size of the RF bonding pad 310 (about 75 um*84 um). As the stack inductor L51 is disposed under the RF bonding pad 310, the chip area can be saved substantially, and further reduce the fabrication cost.

In summary, according to the present invention, the ESD protection unit is disposed under the RF bonding pad, so that the chip area can be saved substantially, and further reduce the fabrication cost. In addition, as the ESD protection unit includes an inductor electrically connected between the RF bonding pad and the power rail, the internal circuit for receiving/emitting RF signal can be protected from damage due to the electrostatic discharge, and at the same time, the normal RF signal transmission is not impacted.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electrostatic discharge (ESD) protection apparatus, comprising:
a substrate;
an radio frequency (RF) bonding pad, disposed upon the substrate, suitable for transmitting RF signal; and
an ESD protection unit, disposed under the RF bonding pad, wherein the ESD protection unit comprises an inductor electrically connected between the RF bonding pad and a power rail.

2. The ESD protection apparatus as claimed in claim 1, wherein the inductor is disposed in stack layout between the RF bonding pad and the substrate.

3. The ESD protection apparatus as claimed in claim 1, wherein the inductor is disposed in spiral layout between the RF bonding pad and the substrate.

4. The ESD protection apparatus as claimed in claim 1, wherein the power rail is a grounded rail.

5. An radio frequency (RF) integrated circuit with electrostatic discharge (ESD) protection, comprising:
a substrate;
a power rail, disposed upon the substrate;
an RF bonding pad, disposed upon the substrate and suitable for transmitting RF signal;
an internal circuit, disposed in the substrate and electrically connected with the RF bonding pad, so as to receive/emit RF signal from/to outside via the RF bonding pad; and
an ESD protection unit, disposed under the RF bonding pad, wherein the ESD protection unit comprises an inductor electrically connected between the RF bonding pad and the power rail.

6. The RF integrated circuit with ESD protection as claimed in claim 5, wherein the inductor is disposed in stack layout between the RF bonding pad and the substrate.

7. The RF integrated circuit with ESD protection as claimed in claim 5, wherein the inductor is disposed in spiral layout between the RF bonding pad and the substrate.

8. The RF integrated circuit with ESD protection as claimed in claim 5, wherein the power rail is a grounded rail.
